(19) United States
(12) Patent Application Publication
(10) Pub. No.: US 2023/0084496 A1
(43) Pub. Date: Mar. 16, 2023

(54) LEAD FRAME, SEMICONDUCTOR DEVICE AND EXAMINATION METHOD

(71) Applicant: SHINKO ELECTRIC INDUSTRIES CO., LTD., Nagano-shi (JP)

(72) Inventors: Shintaro Hayashi, Nagano (JP); Hajime Koike, Nagano (JP)

(21) Appl. No.: 17/942,471

(22) Filed: Sep. 12, 2022

(30) Foreign Application Priority Data
Sep. 14, 2021 (JP) 2021-149756

(51) Int. Cl. H01L 21/66; H01L 23/31; H01L 23/495; H01L 21/48; H01L 21/56; G01B 11/27

(52) U.S. Cl. CPC H01L 22/30; H01L 23/3107; H01L 23/49513; H01L 23/4952; H01L 21/4825; H01L 21/4842; H01L 21/565; G01B 11/272

(57) ABSTRACT

A lead frame includes a die pad that includes a mounting surface for a semiconductor chip, and a film-like member that is arranged on the mounting surface of the die pad. The die pad includes a through hole that is formed in an area that includes an outer periphery of the film-like member.

### CROSS-REFERENCE TO RELATED APPLICATION

This application is based upon and claims the benefit of priority of the prior Japanese Patent Application No. 2021-149756, filed on Sep. 14, 2021, the entire contents of which are incorporated herein by reference.

### FIELD

The embodiment discussed herein is related to a lead frame, a semiconductor device, and an examination method.

### BACKGROUND

In recent years, a semiconductor device in which a semiconductor chip, such as an integrated circuit (IC) chip, is mounted on a lead frame that is made of metal is known. Specifically, for example, a semiconductor chip is mounted on a sheet-like die pad that is arranged in the center of a lead frame, and the semiconductor chip is connected to a plurality of leads that are arranged around the die pad by, for example, wire bonding. Further, the semiconductor device may be formed by encupsulating the semiconductor chip mounted on the lead frame with resin, such as epoxy resin.

The semiconductor chip that is mounted on the die pad may be bonded onto the die pad with, for example, a tape. Specifically, an adhesive tape is attached to the sheet-like die pad and the semiconductor chip is bonded with the tape, so that the semiconductor chip is mounted on the die pad. By mounting the semiconductor chip on the die pad by using, for example, an insulating tape, the semiconductor chip and the die pad are electrically insulated from each other.
Patent Literature 1: Japanese Laid-open Patent Publication No. H8-222585
Patent Literature 2: Japanese Laid-open Patent Publication No. S63-249341
Patent Literature 3: Japanese Laid-open Patent Publication No. H1-147836

When a semiconductor chip is mounted on a die pad by using a tape, a position of the semiconductor chip depends on a position at which the tape is attached. Therefore, it is important to attach the tape at an appropriate position on the die pad, and after a lead frame is manufactured, it is desirable to examine whether the tape is attached to the appropriate position on the die pad.

As a method of examining the position of the tape, a method using transmitted light and a method using reflected light are known. Specifically, it is possible to apply light to a lead frame to which a tape is attached, detect a position of the tape in an image that is formed by transmitted light or reflected light, and determine whether the position of the tape is appropriate.

However, there is a problem in that, with respect to the tape that is attached to the die pad, it is difficult to determine whether the position is appropriate by using the transmitted light or the reflected light. Specifically, the die pad is a sheet-like portion that does not transmit light, and therefore, it is difficult to detect a tape that is attached to the die pad through an examination using the transmitted light. Therefore, in the method using the transmitted light, it is difficult to examine whether the position of the tape attached to the die pad is appropriate.

Furthermore, in an examination using the reflected light, reflection of light at the position of the tape is reduced as compared to a surrounding metal portion, and therefore, it is possible to detect the position of the tape. However, reflection of light is reduced even due to a fine scratch or tone unevenness on a surface of the die pad; therefore, it is difficult to distinguish between the metal portion and the tape depending on a state of the surface of the die pad, and it may be difficult to accurately detect the position of the tape. As a result, it may become difficult to confirm whether the position at which the tape is attached is appropriate, and positional accuracy of a semiconductor chip mounted on the die pad may be reduced.

### SUMMARY

According to an aspect of an embodiment, a lead frame includes a die pad that includes a mounting surface for a semiconductor chip, and a film-like member that is arranged on the mounting surface of the die pad. The die pad includes a through hole that is formed in an area that includes an outer periphery of the film-like member.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a plan view illustrating a configuration of a lead frame according to one embodiment;

FIG. 2 is a diagram for explaining position of through holes;

FIGS. 3A to 3D are diagrams illustrating a specific example of a position of a through hole;

FIGS. 4A to 4D are diagrams illustrating a specific example of a configuration of a tape;

FIG. 5 is a flowchart illustrating a lead frame manufacturing method;

FIG. 6 is a diagram illustrating a specific example of a lead frame molding process;

FIG. 7 is a diagram illustrating a specific example of a plating process;

FIG. 8 is a diagram illustrating a specific example of a tape attaching process;

FIG. 9 is a flowchart illustrating a lead frame examination method;

FIGS. 10A and 10B are diagrams illustrating a specific example of a binary image;

FIG. 11 is a flowchart illustrating a semiconductor device manufacturing method;

FIG. 12 is a diagram illustrating a specific example of a semiconductor chip mounting process;

FIGS. 13A to 13C are diagrams for explaining bonding of a semiconductor chip;

FIG. 14 is a diagram illustrating a specific example of a wire bonding process;

FIG. 15 is a diagram illustrating a specific example of a resin encapsulating process; and

FIG. 16 is a diagram illustrating a specific example of a cutting process.

### DESCRIPTION OF EMBODIMENT

One embodiment of a lead frame, a semiconductor device, an examination method, and a lead frame manufacturing method disclosed in the present application will be described in detail below with reference to the drawings. The present invention is not limited by the embodiment below.

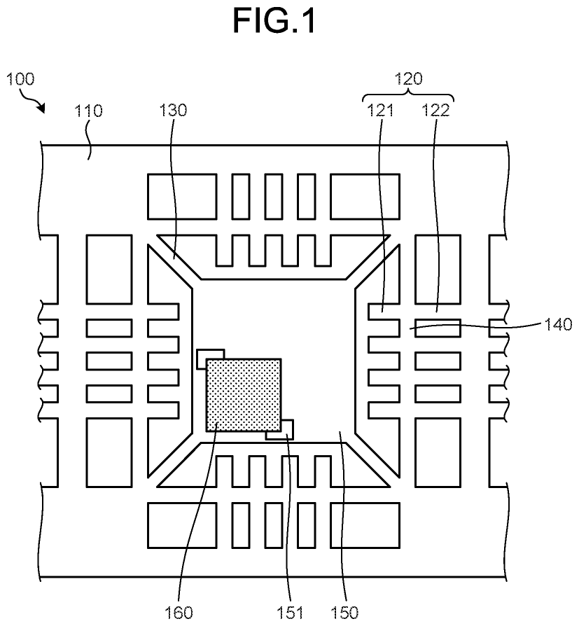

FIG. 1 is a plan view illustrating a configuration of a lead frame 100 according to one embodiment. The lead frame 100 is manufactured as an assembly in which the plurality of lead frames 100 are connected, and therefore, in FIG. 1, the single lead frame 100 in the assembly is illustrated.

The lead frame 100 includes a frame body 110, leads 120, support bars 130, dam bars 140, and a die pad 150. The lead frame 100 is formed of, for example, a metal plate that has a thickness of about 0.1 to 0.25 millimeter (mm) and that is made of copper, copper alloy, or the like.

The frame body 110 defines an outer periphery of the single lead frame 100, and supports the leads 120, the support bars 130, and the die pad 150. At the time of manufacturing the lead frame 100, the plurality of lead frames 100 are manufactured as an assembly in which the lead frames 100 are connected to one another via the frame bodies 110. Further, after a semiconductor chip is mounted on the lead frame 100 and resin encapsulating is performed, the dam bars 140 between the leads 120 are cut and a portion including the leads 120, the support bars 130, and the die pad 150 are separated from the frame body 110, so that an individual semiconductor device is obtained.

The leads 120 form terminals that, when a semiconductor chip is mounted on the lead frame 100, electrically connect the semiconductor chip and external components. Specifically, when a semiconductor chip is mounted on the lead frame 100, the semiconductor chip is connected to the leads 120 by, for example, wire bonding. The plurality of leads 120 that surround the die pad 150 are formed on the lead frame 100 and the adjacent leads 120 are connected to one another by the dam bars 140.

Further, each of the leads 120 includes an inner lead 121 and an outer lead 122. The inner leads 121 are formed at positions located closer to the die pad 150 than the dam bars 140, and are electrically connected to a semiconductor chip mounted on the die pad 150. The outer leads 122 are formed at positions located farther away from the die pad 150 than the dam bars 140, and serve as terminals that are electrically connected to external components. When the semiconductor chip mounted on the die pad 150 is encapsulated with resin, the inner leads 121 are encapsulated with the resin together with the semiconductor chip, but the outer leads 122 are exposed from the resin.

The support bars 130 connect the frame body 110 and the die pad 150, and support the die pad 150. When the semiconductor chip mounted on the die pad 150 is encapsulated with resin, the support bars 130 are encapsulated with the resin together with the semiconductor chip. Further, after resin encapsulating, the support bars 130 are separated from the frame body 110.

The dam bars 140 connect the plurality of leads 120 that are arranged parallel to one another, and connect the plurality of leads 120 to the frame body 110. The dam bars 140 are cut after the semiconductor chip mounted on the die pad 150 is encapsulated with resin, so that the leads 120 connected by the dam bars 140 are separated from one another.

The die pad 150 is a sheet-like area that is formed in the center of the lead frame 100, and is connected to the frame body 110 by, for example, the four support bars 130. The die pad 150 has a square or rectangular surface with sides each having a length of about 2 to 20 mm for example, and a semiconductor chip is mounted on the surface. Specifically, a tape 160 is attached to the die pad 150, and a semiconductor chip is bonded at a position of the tape 160. Further, through holes 151 that penetrate through the die pad 150 are formed in certain areas including a part of an outer periphery of the tape 160 that is attached at an appropriate position on the die pad 150. In other words, if the tape 160 is attached to the appropriate position on the die pad 150, a part of the outer periphery of the tape 160 is located in the through holes 151. In the example illustrated in FIG. 1, diagonal vertices of the tape 160 are located in the respective through holes 151.

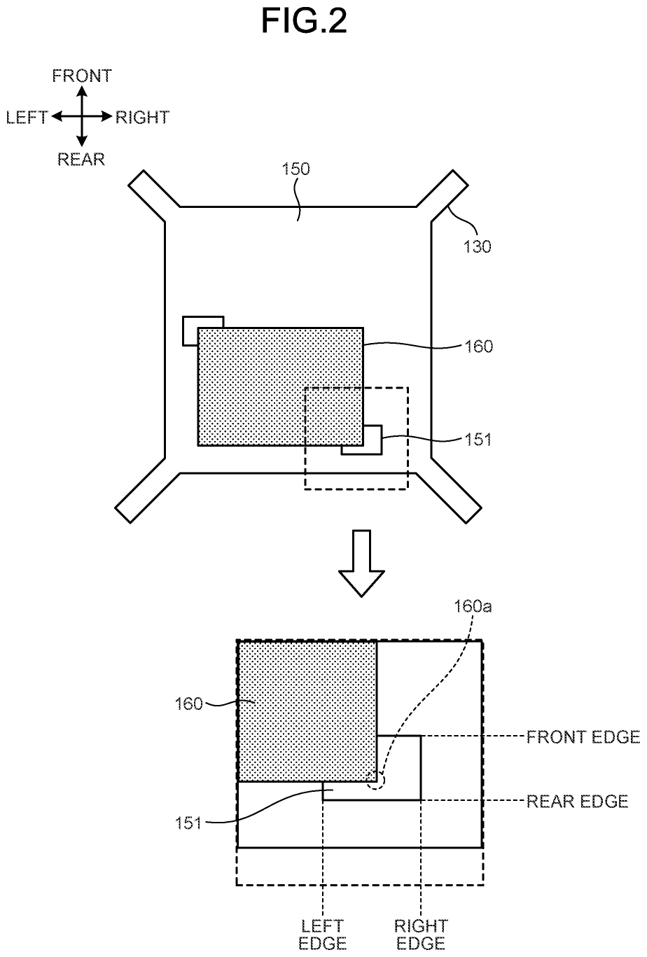

The positions of the through holes 151 will be described below with reference to FIG. 2. FIG. 2 schematically illustrates a shape of the die pad 150, and a lower diagram in FIG. 2 is an enlarged view of a periphery of one of the through holes 151.

As illustrated in FIG. 2, the through holes 151 are formed at two positions on the die pad 150, for example. Each of the through holes 151 is formed so as to include a range in which a vertex 160a that serves as a reference point indicating the position of the tape 160 is located when the tape 160 is attached to an appropriate position. Specifically, each of the through holes 151 is formed so as to have a certain size equal to or larger than a predetermined range in which the vertex 160a serving as the reference point may be located.

More specifically, as illustrated in the lower diagram in FIG. 2, a front side that is located ahead of the position of the vertex 160a when the tape 160 is attached on the frontmost side in a range of an appropriate position serves as a front edge of the through hole 151, and a rear side that is located behind the position of the vertex 160a when the tape 160 is attached on the rearmost side in the range of the appropriate position serves as a rear edge of the through hole 151. Similarly, a left side that is located on the left side relative to the position of the vertex 160a when the tape 160 is attached at the leftmost side in the range of the appropriate position serves as a left edge of the through hole 151, and a right side that is located on the right side relative to the position of the vertex 160a when the tape 160 is attached at the rightmost side in the range of the appropriate position serves as a right edge of the through hole 151. In this manner, each of the through holes 151 is formed so as to have a certain size corresponding to an error range that is allowable as an attachment position of the tape 160, and formed in a square shape or a rectangular shape with sides each having a length of about 0.4 to 2 mm, for example.

As described above, each of the through holes 151 penetrates through the die pad 150 in an area in which the reference point of the tape 160 may be located when the tape 160 is attached to the appropriate position. Therefore, if the tape 160 is attached to the appropriate position, the vertices 160a serving as the reference points of the tape 160 are located in the through holes 151. Consequently, if light is applied to the die pad 150, it is possible to generate an image in which coordinates of the reference points of the tape 160 are detectable by transmitted light that transmits through the through holes 151, so that it is possible to examine whether the tape 160 is attached to the appropriate position.

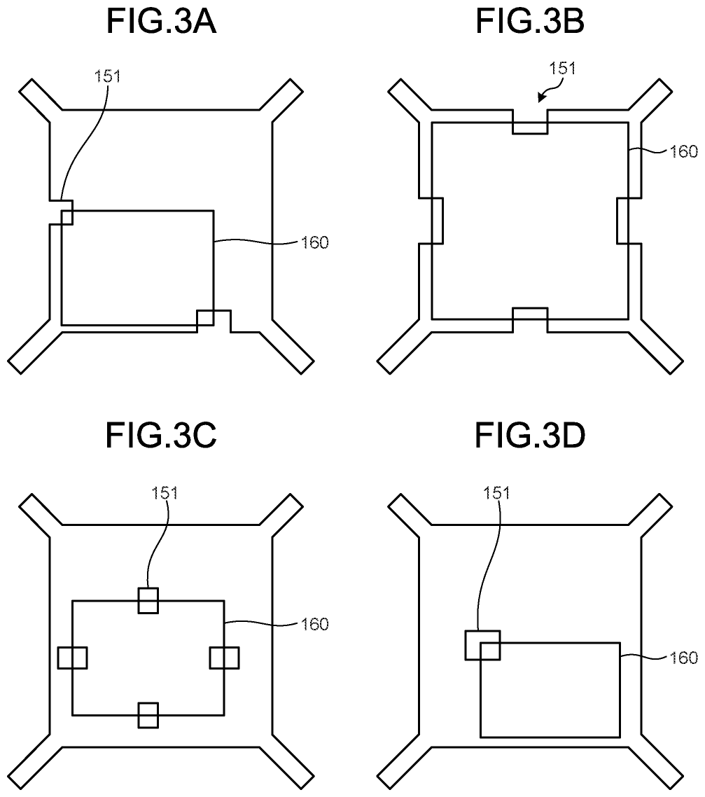

Meanwhile, in FIG. 1 and FIG. 2, the positions of the through holes 151 are illustrated based on the assumption that the diagonal vertices of the tape 160 are used as the reference points, but the positions of the through holes 151 are not limited to this example. Specifically, as illustrated in FIG. 3A for example, even if the diagonal vertices of the tape 160 are used as the reference points, the through holes 151 may be connected to an outer periphery of the die pad 150. In other words, in the example illustrated in FIG. 3A, the through holes 151 are formed in notch shapes on the outer periphery of the die pad 150.

Furthermore, if the tape 160 is to be attached to the entire die pad 150, as illustrated in FIG. 3B for example, the through holes 151 may be formed on four outer sides of the die pad 150 by using four outer sides of the tape 160 as reference lines. Specifically, in the example illustrated in FIG. 3B, the through holes 151 are formed in notch shapes on the four outer sides of the die pad 150, and if the tape 160 is attached to an appropriate position, the four sides of the tape 160 are located in the through holes 151.

Moreover, as illustrated in FIG. 3C for example, the through holes 151 may be formed at four positions on the die pad 150 by using the four outer sides of the tape 160 as reference lines. Even in this case, if the tape 160 is attached to an appropriate position, the four sides of the tape 160 are located in the through holes 151.

Furthermore, as illustrated in FIG. 3D for example, the through hole 151 may be formed at a single position on the die pad 150 by using a single vertex of the tape 160 as a reference point. In this case, if the tape 160 is attached to an appropriate position, the vertex serving as the reference point of the tape 160 is located in the through hole 151.

Meanwhile, the position at which each of the through holes 151 is formed is determined depending on a position at which the tape 160 is to be attached on the die pad 150; however, to reliably bond a semiconductor chip to the die pad 150 with the tape 160, it is preferable to form each of the through holes 151 at a position that does not overlap with the semiconductor chip in a plan view. By adjusting a size of the tape 160 depending on the position at which each of the through holes 151 is formed, it is possible to attach the tape 160 so as to cover a mounting range of the semiconductor chip and such that the reference points are located in the through holes 151. Furthermore, each of the through holes 151 may be formed in various shapes with certain sizes equal to or larger than a predetermined range in which the reference point (line) of the tape 160 is located. Therefore, each of the through holes 151 may be formed in various polygonal shapes, a circle, an ellipse, or the like, instead of a rectangular shape, such as a square or a rectangle.

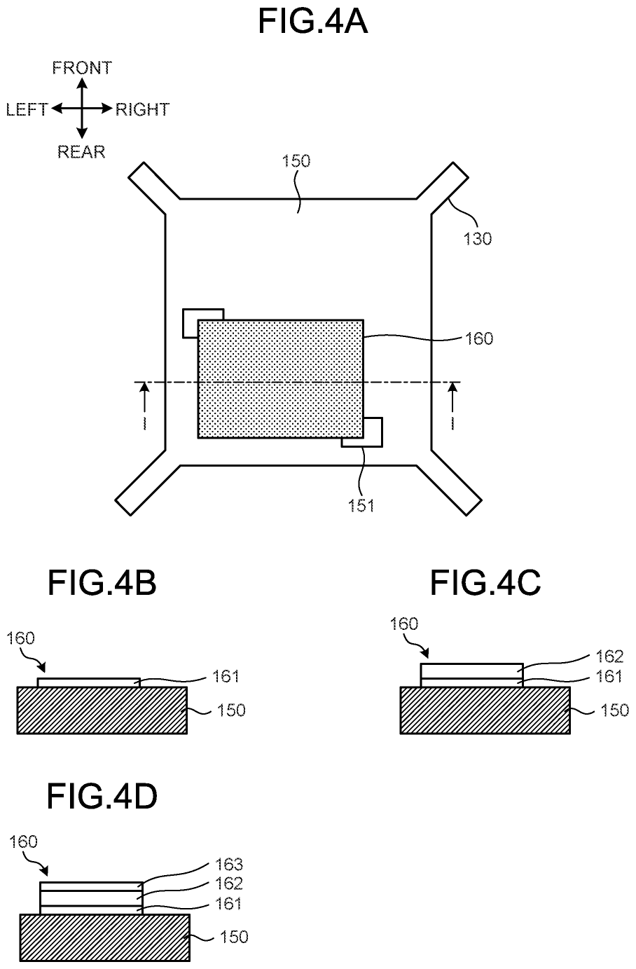

The tape 160 is a film-like member that is attachable to a surface of the die pad 150. The tape 160 has a square shape or a rectangular shape with sides each having a length of about 1 to 20 mm in a plan view, and is attached to a position at which the semiconductor chip is to be mounted on the die pad 150. If the tape 160 is attached at an appropriate position at which the semiconductor chip is expected to be mounted, the reference point or the reference line, such as a predetermined vertex or a predetermined side, of the tape 160 is located in each of the through holes 151. A specific example of a configuration of the tape 160 is illustrated in FIGS. 4A to 4D. In FIGS. 4A to 4D, cross sections cut along a line I-I in FIG. 4A are illustrated in FIG. 4B to FIG. 4D.

As illustrated in FIG. 4B, the tape 160 may be formed of a single bonding layer 161, for example. Specifically, the tape 160 may be formed by attaching the bonding layer 161 that is made of an adhesive material to the die pad 150. The bonding layer 161 may be formed by using insulating resin, such as epoxy, for example. A thickness of the bonding layer 161 may be set to about 10 to 100 micrometers (μm), for example. The tape 160 as described above is formed of the single bonding layer 161, so that both surfaces of the tape 160 have adhesiveness, where one of the surfaces is attachable to the die pad 150 and the other surface is attachable to the semiconductor chip.

Furthermore, as illustrated in FIG. 4C, the tape 160 may have a two-layer structure in which the bonding layer 161 is laminated on one surface of a base material layer 162, for example. Specifically, the tape 160 may be formed by attaching the bonding layer 161 laminated on the base material layer 162 to the die pad 150. The base material layer 162 may be formed by using insulating resin, such as polyimide, for example. A thickness of the bonding layer 161 may be set to, for example, about 10 to 50 μam, and a thickness of the base material layer 162 may be set to, for example, about 50 to 100 μm. Therefore, a thickness of the tape 160 may be set to, for example, about 60 to 150 μm. In the tape 160 as described above, because the bonding layer 161 is laminated on one surface of the base material layer 162, so that a surface of the tape 160 at a side of the bonding layer 161 is attached to the die pad 150. When a semiconductor chip is to be mounted on the tape 160, the semiconductor chip is bonded by forming a bonding layer on a surface of the base material layer 162.

Moreover, as illustrated in FIG. 4D, the tape 160 may have a three-layer structure in which the bonding layer 161 and a bonding layer 163 are laminated on both surfaces of the base material layer 162, for example. Specifically, the tape 160 may be formed by attaching the bonding layer 161 laminated on the base material layer 162 to the die pad 150, and exposing the bonding layer 163 on a top surface. The bonding layer 163 may be formed by using insulating resin, such as epoxy, similarly to the bonding layer 161, for example. A thickness of each of the bonding layers 161 and 163 may be set to, for example, about 10 to 50 μm, and a thickness of the base material layer 162 may be set to, for example, about 50 to 100 μm. Therefore, a thickness of the tape 160 may be set to, for example, about 70 to 200 μm. In the tape 160 as described above, the bonding layers 161 and 163 are formed on the both surfaces of the tape 160, so that the bonding layer 161 is attachable to the die pad 150 and the bonding layer 163 is attachable to the semiconductor chip.

In this manner, it is possible to attach the tape 160 with various configurations to the die pad 150, so that by appropriately selecting the tape 160 with a desired thickness, it is possible to adjust a distance between the die pad 150 and a semiconductor chip bonded to the tape 160.

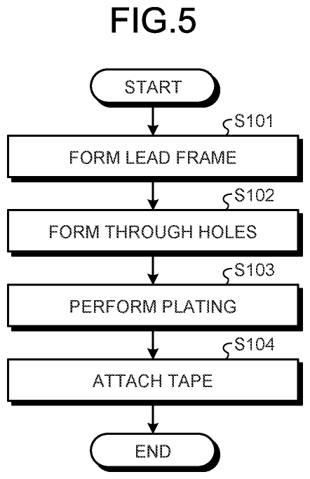

A method of manufacturing the lead frame 100 configured as described above will be described below with reference to a flowchart illustrated in FIG. 5.

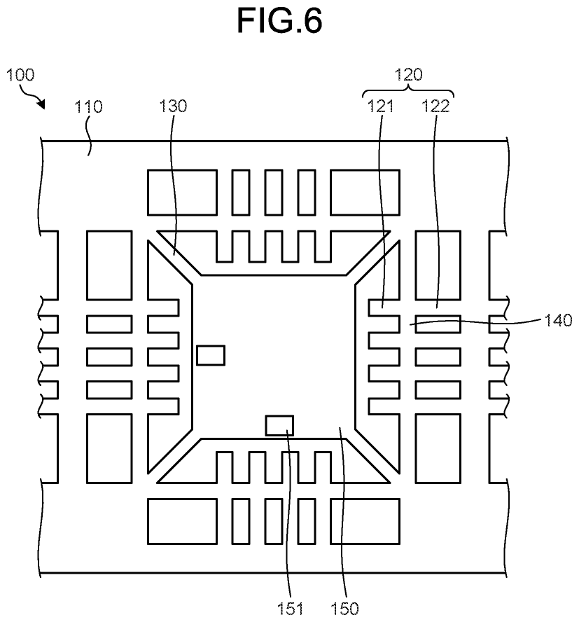

First, the lead frame 100 is formed by performing stamping or etching on a metal plate that has a thickness of, for example, about 0.1 to 0.25 mm and that is made of copper, copper alloy, or the like (Step S101). Further, at the same time of forming the lead frame 100, the through holes 151 are formed in the die pad 150 (Step S102). Specifically, as illustrated in FIG. 6 for example, the leads 120, the support bars 130, the dam bars 140, and the die pad 150 are formed in an area surrounded by the frame body 110 by removing unnecessary portions of the metal plate by stamping or etching. Further, the through holes 151 are formed in the die pad 150.

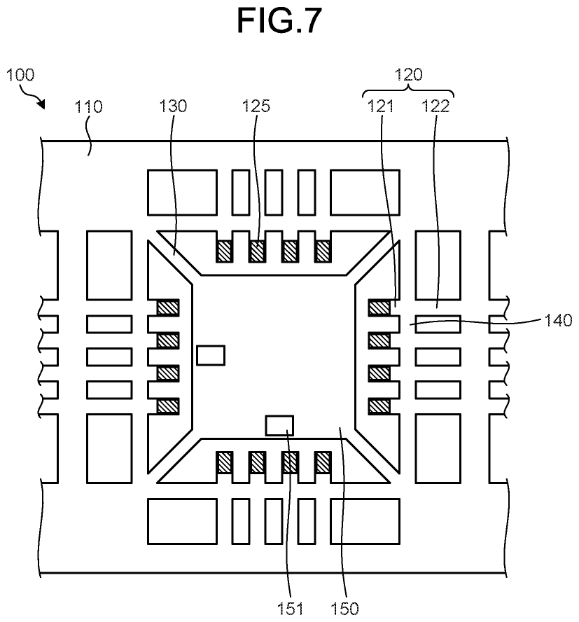

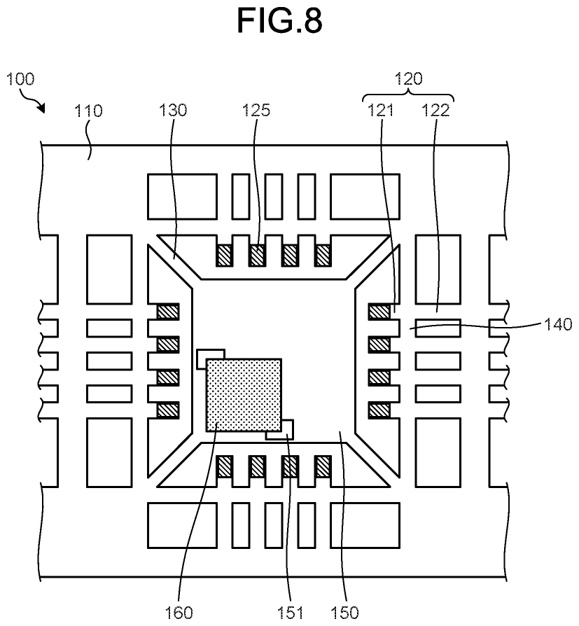

Then, plating is performed on the inner leads 121 included in the leads 120 (Step S103). Specifically, as illustrated in FIG. 7 for example, plating layers 125 are formed at positions at which wires of the inner leads 121 are connected. The plating layers 125 are formed by, for example, silver plating. Meanwhile, in the figures except for FIG. 7 and FIG. 8, illustration of the plating layers 125 is omitted.

After the plating layers 125 are formed, the tape 160 is attached to the die pad 150 (Step S104). Specifically, the bonding layer 161 of the tape 160 is attached to a position at which a semiconductor chip is to be mounted on the die pad 150, so that the tape 160 is attached. At this time, as illustrated in FIG. 8, if the tape 160 is attached to an appropriate position, predetermined vertices or predetermined sides serving as reference points or reference line of the tape 160 are located in the through holes 151.

Through the processes as described above, the lead frame 100 in which a semiconductor chip is mountable on the tape 160 that is attached to the die pad 150 is completed. The position of the semiconductor chip on the die pad 150 is determined depending on the position of the tape 160, so that the tape 160 needs to be attached to the appropriate position. The through holes 151 are formed in the die pad 150 of the lead frame 100 that is manufactured through the processes as described above; therefore, it is possible to efficiently examine whether the tape 160 is attached to the appropriate position.

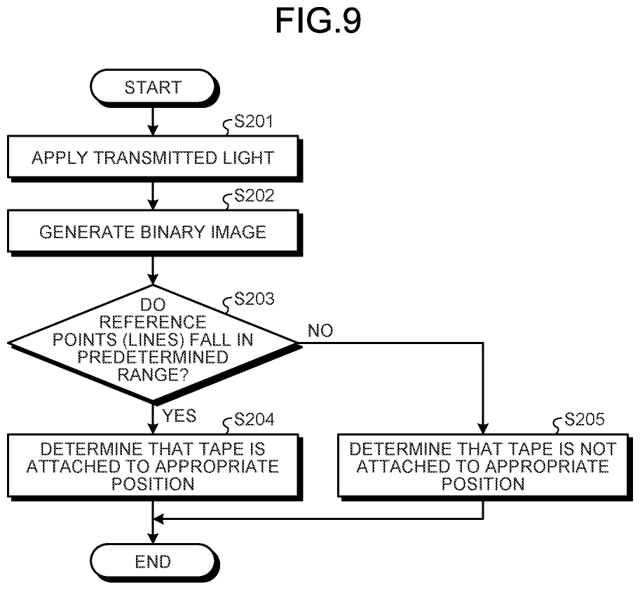

FIG. 9 is a flowchart illustrating a method of examining the lead frame 100. The lead frame 100 is examined by an examination device that includes, for example, a light source, an optical sensor, and an image processing device.

If the lead frame 100 in which the tape 160 is attached to the die pad 150 is completed, the light source applies transmitted light that transmits through the through holes 151 to the lead frame 100 (Step S201). Specifically, the optical sensor is arranged at a side opposite to the light source across the lead frame 100, and light from the light source is blocked by the frame body 110, the leads 120, the support bars 130, the dam bars 140, and the die pad 150, and transmits through only opening portions including the through holes 151 of the die pad 150. Then, the optical sensor detects the transmitted light that has transmitted through the opening portions of the lead frame 100. If the optical sensor detects the transmitted light, a binary image that indicates an area in which the light is blocked and an area through which the light has transmitted is generated (Step S202).

Further, areas corresponding to the through holes 151 of the die pad 150 are identified in the binary image, and coordinates of the reference points or the reference lines of the tape 160 are detected in the areas. Specifically, in the areas corresponding to the through holes 151 in the binary image, areas in which the light is blocked by the tape 160 are identified, and coordinates of predetermined vertices, predetermined sides, or the like of the areas corresponding to the tape 160 are detected. In this manner, if the reference points or the reference lines of the tape 160 are located in the through holes 151, it is possible to detect the coordinates of the reference points or the reference lines of the tape 160 in the binary image. Further, it is determined whether the detected coordinates of the reference points or the reference liens of the tape 160 fall in a predetermined range corresponding to an appropriate attachment position (Step S203). Specifically, it is determined whether the reference points or the reference lines are located in a certain range in which the tape 160 is attached with an allowable error.

As a result of the determination, if the reference points or the reference lines of the tape 160 fall in the predetermined range (Yes at Step S203), it is determined that the tape 160 is attached to the appropriate position (Step S204). In contrast, if the reference points or the reference lines of the tape 160 do not fall in the predetermined range (No at Step S203), it is determined that the tape 160 is not attached to the appropriate position (Step S205).

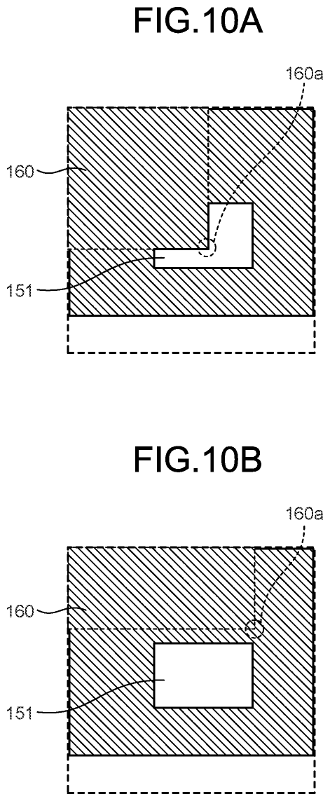

Specifically, as illustrated in FIG. 10A for example, a part of the area of the through hole 151 in the binary image is an area corresponding to the tape 160 that has blocked the light, and if the coordinate of the vertex 160a serving as the reference point of the tape 160 falls in the predetermined range, it is determined that the position of the tape 160 is appropriate. In contrast, even when the vertex 160a serving as the reference point of the tape 160 is included in the area of the through hole 151, if the coordinate of the vertex 160a does not fall in the predetermined range, it is determined that the position of the tape 160 is not appropriate. Furthermore, as illustrated in FIG. 10B for example, if the entire area of the through hole 151 corresponds to an area through which the light has transmitted in the binary image, the vertex 160a serving as the reference point of the tape 160 is not included in the area of the through hole 151, so that it is determined that the position of the tape 160 is not appropriate. Moreover, even if the entire are of the through hole 151 corresponds to an area in which the light is blocked in the binary image, the vertex 160a serving as the reference point of the tape 160 is not included in the area of the through hole 151, so that it is determined that the position of the tape 160 is not appropriate.

In this manner, by forming each of the through holes 151 in an area including a part of the outer periphery of the tape 160 that is attached to an appropriate position on the die pad 150, it is possible to detect the coordinate of the reference point or the reference line of the tape 160 by using the transmitted light, so that it is possible to examine whether the tape 160 is attached to the appropriate position.

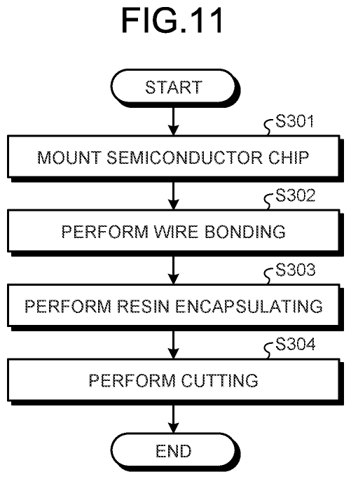

A method of manufacturing a semiconductor device that is configured using the lead frame 100 will be described below with reference to a flowchart illustrated in FIG. 11. The lead frame 100 used to manufacture the semiconductor device is a lead frame for which it is determined that the tape 160 is attached to the appropriate position on the die pad 150 through the examination as described above.

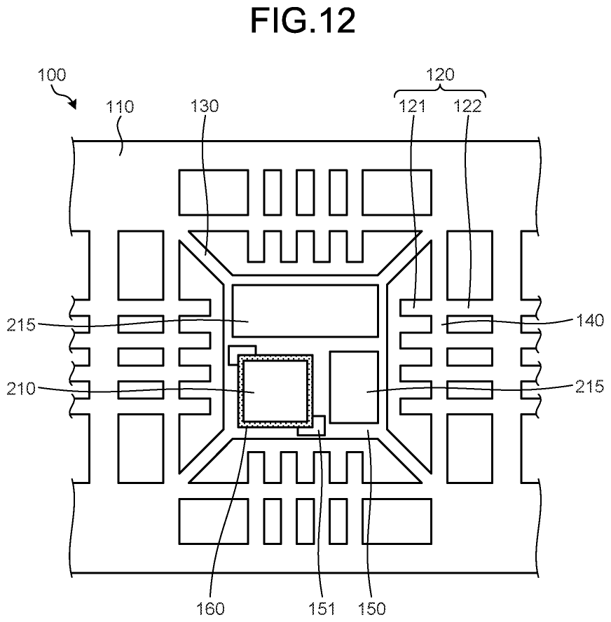

A semiconductor chip is mounted on the die pad 150 of the lead frame 100 (Step S301). Specifically, as illustrated in FIG. 12 for example, a semiconductor chip 210 is bonded at the position of the tape 160. Meanwhile, it may be possible to mount, for example, a semiconductor chip 215 that is bonded with solder, die attach paste, or the like on the die pad 150, in addition to the semiconductor chip 210 that is bonded with the tape 160.

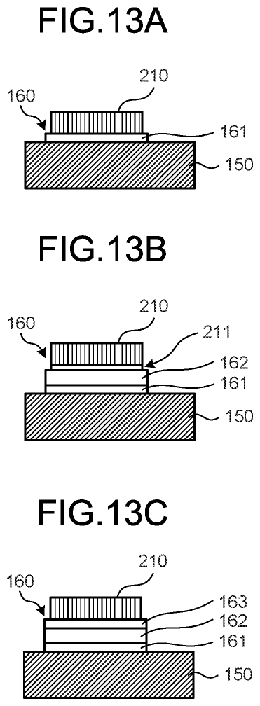

The semiconductor chip 210 that is bonded with the tape 160 has a certain size that falls in a range of the tape 160 in a plan view, and an entire surface of the semiconductor chip 210 is bonded to the tape 160. In this case, as illustrated in FIG. 13A for example, if the tape 160 is formed of the single bonding layer 161, the semiconductor chip 210 is directly bonded to the bonding layer 161. Furthermore, as illustrated in FIG. 13B for example, if the tape 160 has a two-layer structure including the bonding layer 161 and the base material layer 162, a bonding layer 211 is formed on the surface of the base material layer 162, and the semiconductor chip 210 is bonded to the bonding layer 211. Moreover, as illustrated in FIG. 13C for example, if the tape 160 has a three-layer structure including the bonding layer 161, the base material layer 162, and the bonding layer 163, the semiconductor chip 210 is bonded to the bonding layer 163.

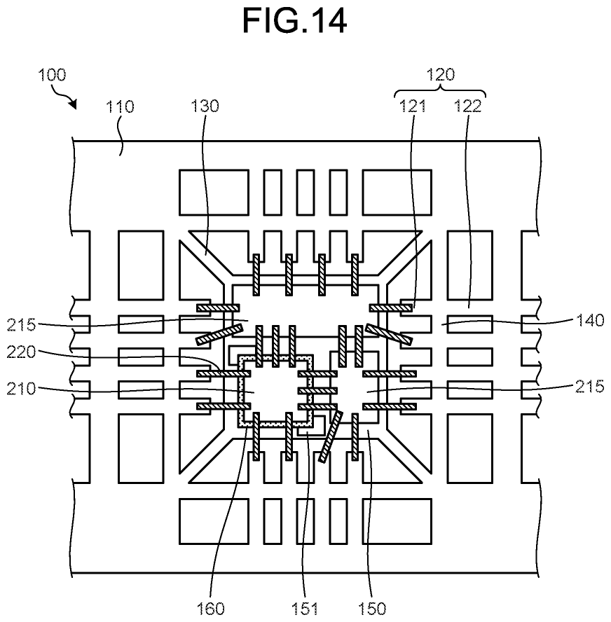

If the semiconductor chip 210 is mounted on the die pad 150, the leads 120 and the semiconductor chip 210 are electrically connected by wire bonding (Step S302). Further, if the plurality of semiconductor chips 210 and 215 are mounted on the die pad 150, the semiconductor chips 210 and 215 may be connected to each other by wire bonding. Specifically, as illustrated in FIG. 14 for example, the plating layers 125 of the inner leads 121 and terminals of the semiconductor chip 210 are connected to one another by wires 220. Furthermore, terminals of the adjacent semiconductor chips 210 and 215 are connected to one another by the wires 220.

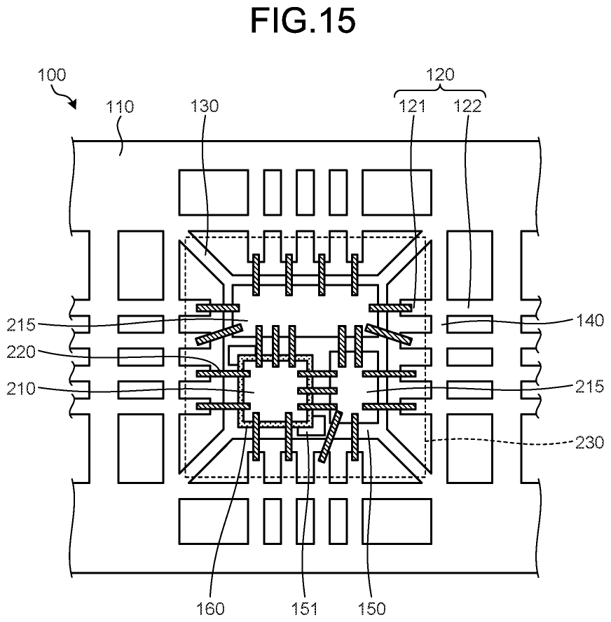

Moreover, the semiconductor chips 210 and 215 are encapsulated with mold resin, such as epoxy resin (Step S303). Specifically, the die pad 150 on which the semiconductor chips 210 and 215 are mounted, the inner leads 121, and the support bars 130 are encapsulated with mold resin 230 in a range indicated by a dashed line in FIG. 15, for example.

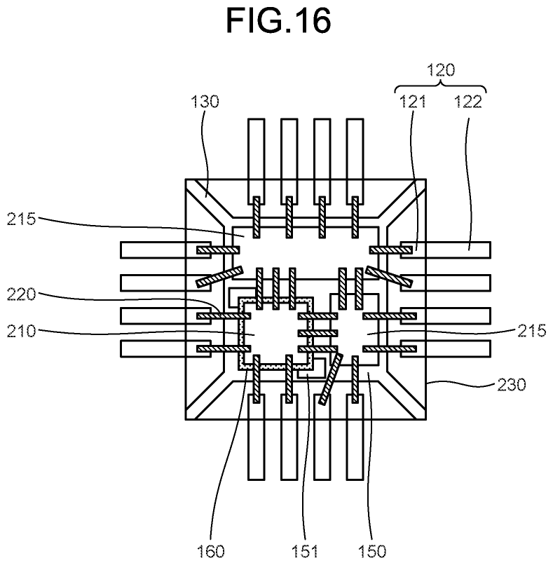

After the semiconductor chips 210 and 215 are encapsulated with resin, the leads 120 and the support bars 130 are separated from the frame body 110, and the dam bars 140 that connect the adjacent leads 120 are cut. Consequently, cutting is performed to obtain an individual semiconductor device, and a semiconductor device using the lead frame 100 is completed (Step S304). The semiconductor device has a certain shape in which the outer leads 122 protrude outward from the mold resin 230 as illustrated in FIG. 16, for example. The outer leads 122 serve as terminals that are connected to outside.

As described above, according to the present embodiment, the tape for bonding a semiconductor chip is attached to the die pad of the lead frame, and a through hole that penetrates through the die pad is formed in an area that includes a part of an outer periphery of the tape that is attached to an appropriate position. Therefore, it is possible to determine whether the position of the outer periphery of the tape is appropriate through an examination using transmitted light, and it is possible to examine whether the tape is attached to an appropriate position on the die pad. As a result, the position of the tape on the lead frame becomes appropriate, so that it is possible to prevent reduction in positional accuracy of a semiconductor chip that is bonded with the tape.

Meanwhile, in one embodiment as described above, the lead frame 100 that is used for a quad flat package (QFP) in which the outer leads 122 protrude outward from the mold resin 230 has been described as one example, but the present invention is not limited to this example. A die pad that includes a through hole similarly to one embodiment as described above may be applicable to a lead frame of various semiconductor devices, such as a quad flat non-leaded package (QFN).

The disclosed technology has been conceived in view of the foregoing situations, and an object of the disclosed technology is to provide a lead frame, a semiconductor device, an examination method, and a lead frame manufacturing method capable of preventing reduction in positional accuracy of a semiconductor chip.

In one embodiment as described above, a lead frame manufacturing method includes:

forming, from a metal plate, a die pad and a plurality of leads, the die pad including a through hole in a mounting surface for a semiconductor chip; and

attaching a film-like member to the mounting surface in which the through hole is formed, wherein

the forming includes forming the through hole in an area that includes an outer periphery of the film-like member.

According to one embodiment of a lead frame, a semiconductor device, an examination method, and a lead frame manufacturing method disclosed in the present application, it is possible to prevent reduction in positional accuracy of a semiconductor chip.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A lead frame comprising:
a die pad that includes a mounting surface for a semiconductor chip; and
a film-like member that is arranged on the mounting surface of the die pad, wherein
the die pad includes a through hole that is formed in an area that includes an outer periphery of the film-like member.

2. The lead frame according to claim 1, wherein the through hole is formed in an area that includes a vertex of the film-like member.

3. The lead frame according to claim 1, wherein the through hole is formed in an area that includes a side of the film-like member.

4. The lead frame according to claim 1, wherein the through hole is connected to an outer periphery of the die pad.

5. The lead frame according to claim 1, wherein the film-like member is formed by using insulating resin.

6. A semiconductor device comprising:
a lead frame;
a semiconductor chip that is mounted on the lead frame; and
encapsulating resin that encapsulates the semiconductor chip, wherein
the lead frame includes
a die pad that includes a mounting surface for the semiconductor chip; and
a film-like member that is arranged on the mounting surface of the die pad and that bonds the semiconductor chip to the die pad, and
the die pad includes a through hole that is formed in an area including an outer periphery of the film-like member.

7. The semiconductor device according to claim 6, wherein the through hole is formed in an area that includes a vertex of the film-like member.

8. The semiconductor device according to claim 6, wherein the through hole is formed in an area that includes a side of the film-like member.

9. The semiconductor device according to claim 6, wherein the through hole is connected to an outer periphery of the die pad.

10. The semiconductor device according to claim 6, wherein the film-like member is formed by using insulating resin.

11. An examination method for a lead frame that includes a die pad including a mounting surface for a semiconductor chip, and a film-like member that is arranged on the mounting surface of the die pad, the die pad including a through hole that is formed in an area including an outer periphery of the film-like member, the examination method comprising:
applying light to the lead frame;
detecting transmitted light that transmits through the through hole of the die pad; and
determining whether the film-like member is positioned in a reference position by using the detected transmitted light.
